(19) United States
(12) Patent Application Publication
(10) Pub. No.: US 2013/0236708 A1
(43) Pub. Date: Sep. 12, 2013

(54) Process for Producing Metallic Structures

(71) Applicants: Karsten Moh, Saarbruecken (DE); Peter William de Oliveira, Saarbruecken (DE); Sarah Schumacher, Saarbruecken (DE); Eduard Arzt, Saarbruecken (DE)

(72) Inventors: Karsten Moh, Saarbruecken (DE); Peter William de Oliveira, Saarbruecken (DE); Sarah Schumacher, Saarbruecken (DE); Eduard Arzt, Saarbruecken (DE)

(73) Assignee: Leibniz-Institut Fuer Neue Materialien gemeinnuetzige GmbH, Saarbruecken (DE)

(21) Appl. No.: 13/988,515

(22) PCT Filed: Nov. 23, 2011
(86) PCT No.: PCT/EP11/70857

§ 371 Date: May 21, 2013

(30) Foreign Application Priority Data
Nov. 23, 2010 (DE) 10 2010 052 032.3

(51) Int. Cl. C23C 16/48

(52) U.S. Cl. CPC C23C 16/48
USPC 428/209; 427/553; 427/535

(57) ABSTRACT

A process for producing metallic structures includes an initiator composition comprising photocatalytic nanorods being applied to a substrate. A precursor composition is applied to the layer, and is reduced to form a metal by the photocatalytic activity of the nanorods. High-resolution metallic structures can be obtained by structured exposure.

### FIELD OF THE INVENTION

The invention relates to a process for producing metallic, especially conductive, structures, and to such substrates and to the use thereof.

### STATE OF THE ART

U.S. Pat. No. 5,534,312 describes a method for producing a metallic structure by applying a light-sensitive metal complex to a substrate and the decomposition thereof by irradiation. This process is complicated, since a light-sensitive complex has to be handled. Moreover, metal oxides are typically formed, and these have to be reduced to the metals in a further step with hydrogen at high temperatures usually exceeding 200° C.

Document US 2004/0026258 A1 describes a process in which a microstructure is first produced on a substrate. These structures serve as nuclei for a further electrolytic deposition operation. In this process too, a reduction step is required as well as the deposition operation.

US 2005/0023957 A1 describes the production of a one-dimensional nanostructure. For this purpose, a coating of a photocatalytic compound is applied on a substrate and exposed through a mask. This forms excited states in the exposed regions. Metals are then deposited electrolytically on this latent image. A disadvantage of this method is the short lifetime of the latent image, which requires immediate further treatment. Moreover, a further deposition step is also required in this method in order to obtain conductive structures.

In document US 2006/0144713 A1, a polymer is applied to the photocatalytic compound in order to extend the lifetime of the excited state. This makes this process even more complicated. In the publications Noh, C.-, et al., Advances in Resist Technology and Processing XXII, Proceedings of SPIE, 2005, 5753, 879-886, “A novel patterning method of low-resistivity metals” and Noh, C.-, et al., Chemistry Letters, 2005 34(1), 82-83, “A novel patterning method of low-resistivity metals”, it is stated that it is also possible to use a layer of amorphous titanium dioxide as the photocatalytic layer. However, in the case of use of crystalline titanium dioxide nanoparticles, it was not possible to achieve sufficient resolution of the structures, probably due to the size of the particles, which leads to a rough surface. Owing to the relatively low photocatalytic activity of amorphous titanium dioxide, it is possible to photocatalytically deposit only a small amount of metal.

Document US 2009/0269510 A1 describes the production of metallic films on a coating of titanium dioxide nanoparticles. For this purpose, spherical particles having a diameter between 3 nm and nm are used. This process can achieve a certain degree of structuring. However, the structures are not transparent and have only low resolution.

The publication Jia, Huimin et al., Materials Research Bulletin, 2009, 44, 1312-1316, “Nonaqueous sol-gel synthesis and growth mechanism of single crystalline TiO₂ nanorods with high photocatalytic activity” demonstrates the use of nanorods of titanium dioxide for the production of silver coatings by exposure.

It would be advantageous if it were also possible to produce transparent conductive structures by photocatalytic deposition, a problem which has to date usually been solved by means of ITO coatings.

### Problem

The problem addressed by the invention is that of specifying a process which enables the production of metallic structures in a simple manner, especially of conductive structures. The process is also to enable the production of transparent structures.

This problem is solved by the inventions having the features of the independent claims. Advantageous developments of the inventions are characterized in the dependent claims. The wording of all claims is hereby incorporated by reference into the content of this description. The inventions also encompass all viable and especially all mentioned combinations of independent and/or dependent claims.

The problem is solved by a process for producing metallic structures, wherein an initiator composition is applied to a substrate, the composition comprising photocatalytically active nanorods as an initiator. In a further step, a precursor composition comprising at least one precursor compound for a metal layer is applied to the substrate. In a further step, the precursor compound is reduced to the metal under the action of electromagnetic radiation on the initiator.

This typically forms a metal layer. A metallic layer is understood here in the context of the invention to mean a layer of a metal. Such layers, given sufficient thickness, may also be conductive. Such conductive layers are particularly preferred. “Conductive” is not necessarily understood to mean the production of structures which intrinsically constitute a conductor track. The production of dots of conductive material also constitutes a structure which is conductive in principle.

Individual process steps are described in detail hereinafter. The steps need not necessarily be conducted in the sequence specified, and the process to be outlined may also have further unspecified steps.

The process described has the advantage that the nanorods used have better photochemical reactivity than corresponding nanoparticles or amorphous titanium dioxide. As a result, it is possible not just to reduce the precursor compound directly to metal but also to ensure conductive structures in a sufficient amount. Since the precursor compound itself is light-sensitive only to a minor degree, if at all, it can be handled much more easily.

The substrate which is to be coated with the photocatalytic initiator may be any material suitable for this purpose. The examples of suitable materials are metals or metal alloys, glass, ceramic, including oxide ceramic, glass ceramic or polymers, and also paper and other cellulosic materials. It is of course also possible to use substrates having a surface layer of the aforementioned materials. The surface layer may, for example, arise from a metallization or enameling operation, be a glass or ceramic layer, or arise from a painting operation.

Examples of metals or metal alloys are steel, including stainless steel, chromium, copper, titanium, tin, zinc, brass and aluminum. Examples of glass are soda-lime glass, borosilicate glass, lead crystal and silica glass. The glass may, for example, be panel glass, hollow glass such as vessel glass, or laboratory equipment glass. The ceramic may, for example, be a ceramic based on the oxides SiO₂, Al₂O₃, ZrO₂ or MgO, or the corresponding mixed oxides. Examples of the polymer which, like the metal too, may be present in the form of a film, are polyethylene, e.g. HDPE or LDPE, polypropylene, polyisobutylene, polystyrene (PS), polyvinyl chloride (PVC), polyvinylidene chloride, polyvinyl butyral, polytetrafluoroethylene, polychlorotrifluoroethylene, polyacrylates, polymethacrylates such as polymethylmethacrylate (PMMA), polyamide, polyethylene terephthalate (PET), polycarbonate, regenerated cellulose, cellulose nitrate, cellulose acetate, cellulose triacetate (TAC), cellulose acetate butyrate or rubber hydrochloride. A painted surface may be formed from standard basecoats or paints. In a preferred embodiment, the substrates are films, especially polyethylene terephthalate films or polyimide films.

The initiator comprises photocatalytically active nanorods. A photocatalytically active material is understood to mean a compound which brings about the reduction of a metal ion in a metal complex to the metal directly and/or indirectly through oxidative activation of the metal complex or of a further substance, without itself being decomposed in the process. The products which form in the course of oxidation result in decomposition of the metal complex and reduction of the metal ion in the complex. The photocatalytic material may be ZnO or TiO₂, preference being given to TiO₂. More preferably, the TiO₂ is in anatase form.

The initiator composition comprises nanorods. In the context of the invention, these are generally understood to mean elongated bodies, as opposed to spherical nanoparticles. Such a rod-shaped body can be described, for example, on the basis of two parameters: firstly the diameter of the rod and secondly the length of the rod. Nanorods are notable particularly in that they have a diameter of less than 100 nm, preferably less than 50 nm, preferably less than 40 nm, more preferably less than 30 nm. The length thereof is less than 500 nm, preferably less than 400 nm, more preferably less than 200 nm. The dimensions can be determined by means of TEM. The nanorods usually lie on the longer side in TEM. The diameters determined therefore constitute an average of the diameters of nanorods in different orientation. In the composition, agglomerates of nanorods may also occur. The figures are always based on one nanorod.

In a preferred embodiment, the nanorods have a ratio of diameter to length between 1000:1 and 1.5:1, preferably between 500:1 and 2:1, more preferably between 100:1 and 5:1.

In a preferred embodiment, the nanorods have a length between 30 and 100 nm, with a ratio of length to diameter between 10:1 and 3:1.

By virtue of their elongation, the nanorods have particularly high photocatalytic activity.

For production of the nanorods, all processes known to those skilled in the art are useful. These are, for example, hydrolytic or nonhydrolytic sol-gel processes. For such processes, there are known conditions under which nanorods are obtained.

The nanorods are preferably produced by a nonhydrolytic sol-gel process. For this purpose, a hydrolyzable titanium compound and/or zinc compound is reacted with an alcohol or a carboxylic acid, preferably under protective gas atmosphere. The reaction is preferably performed at temperatures between 10° C. and 100° C., preferably between 15° C. and 30° C. In one embodiment, the reaction can be performed at room temperature.

The hydrolyzable titanium compound is especially a compound of the formula TiX₄ where the hydrolyzable X groups, which are different from one another or preferably the same, are, for example, hydrogen, halogen (F, Cl, Br or I, especially Cl and Br), alkoxy (preferably C₁₋₆-alkoxy, especially C₁₋₄-alkoxy, for example methoxy, ethoxy, n-propoxy, i-propoxy, butoxy, i-butoxy, sec-butoxy and tert-butoxy), aryloxy (preferably C₆₋₁₀-aryloxy, for example phenoxy), acyloxy (preferably C₁₋₆-acyloxy, for example acetoxy or propionyloxy) or alkylcarbonyl (preferably C₂₋₇-alkylcarbonyl, for example acetyl). One example of a halide is TiCl₄. Further hydrolyzable X radicals are alkoxy groups, especially C₁₋₄-alkoxy. Specific titanates are Ti (OCH₃)₄, Ti(OC₂H₅)₄ and Ti(n- or i-OC₃H₇)₄. Preference is given to TiCl₄.

In the case of a zinc compound, carboxylic acid compounds of zinc are an option, for example Zn(OAc)₂.

The alcohol and the carboxylic acid are generally lower alcohols and carboxylic acids. Examples of such compounds are alkyl alcohols, such as methanol, ethanol, n-propanol, i-propanol, n-butanol, i-butanol, neopentanol, glycol, 1,3-propanediol or benzyl alcohols such as benzyl alcohol which may also be substituted on the aromatic ring. Examples of carboxylic acids include, for example, formic acid, acetic acid, propionic acid, butyric acid, oxalic acid. It is also possible to use mixtures of the solvents. Preference is given to the use of benzyl alcohol. The compound is preferably also used as a solvent, i.e. in a distinct excess.

In order to obtain crystalline nanorods, it may be necessary also to conduct a heat treatment, preferably a heat treatment under autogenous pressure. For this purpose, the reaction mixture is treated in a closed vessel at a temperature between 50° C. and 300° C., preferably between 50° C. and 100° C., for 2 hours to 48 hours.

The resulting nanorods can be obtained by simple centrifugation and removal of the solvent.

The nanorods may also be doped, for example in order to shift the absorption thereof into other spectral regions.

For this purpose, in the case of the nanorods, in the course of production thereof, a suitable metal compound can be used for doping, for example an oxide, a salt or a complex, for example halides, nitrates, sulfates, carboxylates (e.g. acetates) or acetylacetonates. The compound should appropriately be soluble in the solvent used for the production of the nanorods. A suitable metal is any metal, especially a metal selected from groups 5 to 14 of the periodic table of the elements and the lanthanoids and actinides. The groups are mentioned here in accordance with the new IUPAC system, as shown in Römpp Chemie Lexikon, 9th edition. The metal may occur in the compound in any suitable initial oxidation state.

Examples of suitable metals for the metal compound are W, Mo, Zn, Cu, Ag, Au, Sn, In, Fe, Co, Ni, Mn, Ru, V, Nb, Ir, Rh, Os, Pd and Pt. Metal compounds of W(VI), Mo(VI), Zn(II), Cu(II), Au(III), Sn(IV), In(III), Fe(III), Co(II), V(V) and Pt(IV) are used with preference. Very good results are achieved particularly with W(VI), Mo(VI), Zn(II), Cu(II), Sn(IV), In(III) and Fe(III). Specific examples of preferred metal compounds are WO₃, MoO₃, FeCl₃, silver acetate, zinc chloride, copper(II) chloride, indium(III) oxide and tin(IV) acetate.

The ratio between the metal compound and the titanium or zinc compound also depends on the metal used and the oxidation state thereof. In general, for example, the ratios used are such as to result in a molar ratio of metal in the metal compounds to titanium/zinc in the titanium or zinc compound (Me/Ti(Zn)) of 0.0005:1 to 0.2:1, preferably 0.001:1 to 0.1:1 and more preferably 0.005:1 to 0.1:1.

The resulting nanorods may also be surface modified, for example in order to impart compatibility with the matrix material used. It is also possible, for example through surface modification with fluorinated groups, to achieve a concentration gradient of the nanorods within the initiator layer. The nanorods accumulate at the surface of the initiator layer which is exposed after the application and cannot damage the substrate in the course of irradiation.

The initiator composition generally comprises a dispersion of the nanorods in at least one solvent. The proportion of the nanorods is less than 20% by weight, preferably less than 10% by weight, more preferably less than 5% by weight. A preferred range is between 0.5% by weight and 3% by weight. Examples are 1% by weight, 1.5% by weight, 2% by weight and 2.5% by weight. The proportion here is based on the initiator composition.

Suitable solvents are solvents known to those skilled in the art for nanorods. Preference is given to solvents having a boiling point of less than 150° C. Examples thereof are deionized H₂O, methanol, ethanol, isopropanol, n-propanol or butanol. It is also possible to use mixtures. Examples of such mixtures are H₂O:alcohol between 80:20% by weight and 20:80% by weight, preferably 50:50% by weight to 20:80% by weight, the alcohol used preferably being ethanol.

For application of the initiator composition, it is possible to use standard processes, for example dipping, rolling, knife coating, flow coating, drawing, spraying, spinning or painting. The dispersion applied is optionally dried and heat treated, for instance for curing or consolidation. The heat treatment used for this purpose depends of course on the substrate. In the case of polymer substrates or polymer surfaces, which generally have a barrier layer (see below), it is of course not possible to use very high temperatures. For example, polycarbonate (PC) substrates are heat treated at about 130° C. for 1 h. In general, the heat treatment is effected, for example, at a temperature of 100 to 200° C. and, if no polymer is present, at up to 500° C. or more. The heat treatment is effected, for example, for 2 min to 2 h.

It is possible to obtain layers with different thickness. For instance, it is possible to obtain layers having a thickness between 5 nm and 200 μm. Preferred layer thicknesses are between 10 nm and 1 μm, preferably 50 nm to 700 nm. The layer thickness may also be between 20 μm and 70 μm.

In a next step, a precursor composition comprising at least one precursor compound for a metal layer is applied to the substrate. For application of the precursor composition, it is possible to use customary methods, for example dipping, rolling, knife coating, flow coating, drawing, spraying, spinning or painting. Typically, the precursor composition is a solution or suspension of the at least one precursor compound. This solution may also comprise a mixture of a plurality of precursor compounds. It is also possible for further assistants, such as reducing agents or wetting aids, to be present in the solution.

The precursor compound is preferably a metal complex. This comprises at least one metal ion or a metal atom and at least one kind of ligand. The metal is, for example, copper, silver, gold, nickel, zinc, aluminum, titanium, chromium, manganese, tungsten, platinum or palladium. In a preferred embodiment, the precursor compound is a silver, gold or copper complex, more preferably a silver complex. The precursor compound may also include several types of metal or mixtures of metal complexes.

The ligands used are generally chelate ligands. These are capable of forming particularly stable complexes. These are compounds having a plurality of hydroxyl groups and/or amino groups. Preference is given to compounds having a molecular weight of less than 200 g/mol, particular preference to compounds having at least one hydroxyl group and at least one amino group. Examples of possible compounds are 3-amino-1,2-propanediol, 2-amino-1-butanol, tris(hydroxymethyl)aminomethane (TRIS), NH₃, nicotinamide or 6-aminohexanoic acid. It is also possible to use mixtures of these ligands. In the case of the preferred silver complex, TRIS is preferred as a ligand.

The precursor composition is preferably a solution of the precursor compound. Useful solvents include all suitable solvents. These are, for example, water, alcohols such as methanol, ethanol, n-propanol or i-propanol. It is also possible to use mixtures of the solvents, preferably mixtures of water and ethanol. A suitable mixing ratio is a ratio of 50:50% by weight up to 20:80% by weight of H₂O:alcohol, preferably ethanol.

The precursor composition may additionally comprise further assistants, such as surfactants or promoting reducing agents.

The precursor composition can be applied to the substrate in any desired manner. The precursor composition is applied in such a way that the photocatalytic activity of the initiator layer can directly or indirectly trigger the reduction of the metal ion to the metal. This is typically done by applying the precursor composition directly to the initiator layer.

For application of the precursor composition, it is possible to use customary methods, for example dipping, spraying, rolling, knife coating, flow coating, drawing, spinning or painting.

For example, the application of the precursor composition can be achieved by means of a frame which is placed onto the substrate and the precursor composition is introduced into the space bounded by the frame which is then formed. The frame may consist of an elastic material. The frame may have any desired shapes. A rectangular frame is customary. The frame encloses, for example, an area on the substrate of between 1 cm² and 625 cm² with a side length between 1 cm and 25 cm. The height of the frame on the substrate determines the thickness of the precursor composition applied. The frame may have a height between 25 μm and 5 mm, preferably between 30 μm and 2 mm.

In a next step, the metal ion of the precursor compound is reduced to the metal by the action of electromagnetic radiation on the initiator. This forms a metallic layer. The electromagnetic radiation is radiation of the wavelength for excitation of the initiator. The irradiation can be accomplished by use of a large-area radiation source such as a lamp, or by means of lasers. Preference is given to using a wavelength in the visible or ultraviolet (UV) region of the electromagnetic spectrum, preferably radiation having a wavelength of <500 nm, for example between 200 and 450 nm or between 250 nm to 410 nm. It is preferable radiation having a wavelength of <400 nm.

The light source used may be any suitable light source. Examples of a light source are mercury vapor lamps or xenon lamps.

The light source is arranged at a suitable distance from the substrate to be exposed. The distance may, for example, be between 2.5 cm and 50 cm. The intensity of the radiation may be between 30 mW/cm² and 70 mW/cm² within a spectral range from 250 nm to 410 nm.

The irradiation should if possible be effected at right angles to the surface to be exposed.

The irradiation is performed in the duration sufficient for formation of the metallic layer. The duration depends on the coating, the type of initiator, the type of lamp, the wavelength range used and the intensity of irradiation. If conductive structures are to be produced, longer irradiation may be required. Preference is given to a duration of the irradiation between 5 seconds and 10 minutes, preferably between 20 seconds and 4 minutes.

If a laser is used for irradiation, it is possible, for example, to use a 10 mW argon ion laser (351 nm), the focused and collimated laser beam of which is conducted over the substrate to be irradiated at a speed of 2 mm/s.

In a further embodiment of the invention, the substrate is treated further after the treatment and reduction of the precursor compound. For example, the unreduced excess precursor composition can be removed by rinsing the surface, for example with deionized water or another suitable substance. The coated substrate can then be dried, for example by heating in an oven, compressed air and/or by drying at room temperature.

It is also possible to apply further layers, for example for protection of the coated surface from oxidation and water or from UV radiation.

In a preferred embodiment of the invention, structuring is effected in the course of application of the precursor composition and/or in the course of reduction. In the context of the invention, this is understood to mean a preparation of the spatially limited production of the metallic structure. This is possible in different ways. Firstly, the substrate can be coated with the initiator composition only in particular regions. It is also possible to apply the precursor composition only to particular regions. In addition, it is of course also possible to limit the action of electromagnetic radiation to particular regions. These processes can of course also be used in combination. For example, it is possible to apply the precursor composition over a large area and then to expose it through a mask. It is of course likewise possible to apply the precursor composition selectively and then to expose the whole area.

Important factors for the quality of the structures obtained are not only the photocatalytic activity of the initiator but also the quality, for example the wettability or roughness, of the initiator layer in relation to the precursor composition. Specifically the inventive initiator compositions are notable in that controlled application of the precursor composition and/or very controlled reduction of the precursor compound are possible thereon.

In a preferred embodiment of the invention, the structuring comprises structures having a minimum lateral dimension of less than 500 μm. This means that the structures produced on the substrate have a minimum width of 500 μm, preference being given to a dimension of less than 100 μm, 50 μm, 20 μm, more preferably 10 μm.

An important factor for the resolution of the metallic structures achieved, i.e. the formation of the metal layer, is the structure of the photocatalytic layer formed. As well as the use of the nanorods, it is possible to attain the resolution achieved by a pretreatment of the substrate. Such a pretreatment may also mean the application of a further layer.

In a preferred development of the invention, the pretreatment includes a plasma treatment, corona treatment, flame treatment and/or the application and curing of an organic-inorganic coating. A plasma treatment, corona treatment and/or flame treatment is an option particularly in the case of film substrates, especially in the case of polymer films. It has been found that such a treatment improves the quality of the photocatalytic layer obtained.

Possible ways of maintaining plasma under vacuum conditions have been described frequently in the literature. The electrical energy can be bound by inductive or capacitative means. It may be direct current or alternating current; the frequency of the alternating current may range from a few kHz up to the MHz range. Energy supply in the microwave range (GHz) is also possible.

The primary plasma gases used may, for example, be He, argon, xenon, N₂, O₂, H₂, steam or air, and likewise mixtures of these compounds. Preference is given to an oxygen plasma.

Typically, the substrates are cleaned beforehand. This can be accomplished by simple rinsing with a solvent. The substrates are then optionally dried and then treated with plasma for less than 5 minutes. The treatment time may depend on the sensitivity of the substrate. It is typically between 1 and 4 minutes.

A further means of improving the quality of the photocatalytic layer is prior flame treatment of the surface. Such a treatment is known to those skilled in the art. The parameters to be selected are defined by the particular substrate to be treated. For example, the flame temperatures, the flame intensity, the residence times, the distance between substrate and oven, the nature of the combustion gas, air pressure, moisture, are matched to the substrate in question. The flame gases used may, for example, be methane, propane, butane or a mixture of 70% butane and 30% propane. This treatment too preferably finds use in the case of films, more preferably in the case of polymer films.

In a further embodiment of the invention, the initiator composition comprises a compound having at least 2 polar groups. These are preferably organic compounds. Polar groups are understood to mean groups containing O, N or S. They are preferably compounds which contain at least 2 OH, NH₂, NH or SH groups. Such compounds may lead to an improvement in the initiator layer obtained. Examples of such compounds are oligomers of compounds such as 1,2-ethanediol, 1,3-propanediol, 1,4-butanediol, 1,2-ethylenediamine, 1,3-propanediamine, 1,4-butanediamine, each of which is joined via an oxygen, nitrogen or sulfur atom. In this case, oligomers consist of 2 to 4 of the aforementioned compounds. Examples are monoethylene glycol (MEG), diethylene glycol (DEG), triethylene glycol.

The compound is preferably used in proportions of less than 10% by weight based on the mass of nanorods in the suspension, preferably less than 5% by weight, more preferably between 1 and 4% by weight.

In a preferred embodiment, the initiator composition comprises an inorganic or organically modified inorganic matrix-forming material. This may especially comprise inorganic sols or organically modified inorganic hybrid materials or nanocomposites. Examples thereof are optionally organically modified oxides, hydrolyzates and (poly)condensates of at least one glass- or ceramic-forming element M, especially an element M from groups 3 to 5 and/or 12 to 15 of the periodic table of the elements, preferably of Si, Al, B, Ge, Pg, Sn, Ti, Zr, V and Zn, especially those of Si and Al, most preferably Si, or mixtures thereof. It is also possible for portions of elements of groups 1 and 2 of the periodic table (e.g. Na, K, Ca and Mg) and of groups 5 to 10 of the periodic table (e.g. Mn, Cr, Fe and Ni) or lanthanoids to be present in the oxide, hydrolyzate or (poly)condensate. Preferred organically modified inorganic hybrid materials are polyorganosiloxanes. For this purpose, particular preference is given to using hydrolyzates of glass- or ceramic-forming elements, especially of silicon.

The inorganic or organically modified inorganic matrix-forming material is preferably added in such an amount that the ratio between the nanorods and the matrix-forming material, based on % by weight of the overall composition, is between 300:1 and 1:300, preferably between about 30:1 and 1:30, more preferably between 1:20 and 1:2. This addition achieves an improvement in adhesion. If an organically modified inorganic matrix-forming material is used, all or only some of the glass- or ceramic-forming elements M present may have one or more organic groups as nonhydrolyzable groups.

The inorganic or organically modified inorganic matrix-forming materials can be produced by known processes, for example by flame pyrolysis, plasma processes, gas phase condensation processes, colloid techniques, precipitation processes, sol-gel processes, controlled nucleation and growth processes, MOCVD processes and (micro)emulsion processes.

The inorganic sols and especially the organically modified hybrid materials are preferably obtained by the sol-gel process. In the sol-gel process, which can also be used for separate production of the particles, usually hydrolyzable compounds are hydrolyzed with water, optionally with acidic or basic catalysis, and optionally at least partly condensed. The hydrolysis and/or condensation reactions lead to formation of compounds or condensates having hydroxyl or oxo groups and/or oxo bridges, which serve as precursors. It is possible to use stoichiometric amounts of water, but also smaller or greater amounts. The sol which forms can be adjusted to the viscosity desired for the coating composition by means of suitable parameters, for example degree of condensation, solvent or pH. Further details of the sol-gel process are described, for example, in C. J. Brinker, G. W. Scherer: “Sol-Gel Science—The Physics and Chemistry of Sol-Gel-Processing”, Academic Press, Boston, San Diego, New York, Sydney (1990).

The preferred sol-gel process affords the oxides, hydrolyzates or (poly) condensates by hydrolysis and/or condensation from hydrolyzable compounds of the abovementioned glass- or ceramic-forming elements, which optionally additionally bear nonhydrolyzable organic substituents for production of the organically modified inorganic hybrid material.

Inorganic sols are formed by the sol-gel process particularly from hydrolyzable compounds of the general formulae MX, in which M is the above-defined glass- or ceramic-forming element, X is as defined in formula (I) below, where two X groups may be replaced by an oxo group, and n corresponds to the valency of the element and is usually 3 or 4. Preference is given to hydrolyzable Si compounds, especially of the formula (I) below.

Examples of usable hydrolyzable compounds of elements M other than Si are Al (OCH₃)₃, Al(OC₂H₅)₃, Al(O-n-C₃H₇)₃, Al(O-i-C₃H₇)₃, Al(O-n-C₄H₉)₃, Al(O-sec-C₄H₉)₃, AlCl₃, AlCl(OH)₂, Al(OC₂H₄OC₄H₉)₃, TiCl₄, Ti(OC₂H₅)₄, Ti(O-n-C₃H₇)₄, Ti(O-i-C₃H₇)₄, Ti(OC₄H₉)₄, Ti (2-ethylhexoxy)₄, ZrCl₄, Zr(OC₂H₅)₄, Zr(O-n-C₃H₇)₄, Ar(O-i-C₃H₇)₄, Zr(OC₄H₉)₄, ZrOCl₂, Zr(2-ethylhexoxy)₄, and Zr compounds having complexing radicals, for example β-diketone and (meth)acryloyl radicals, sodium methoxide, potassium acetate, boric acid, BCl₃, B(OCH₃)₃, B(OC₂H₅)₃, SnCl₄, Sn(OCH₃)₄, Sn(OC₂H₅)₄, VOCl₃ and VO(OCH₃)₃.

The remarks which follow regarding the preferred silicon also apply mutatis mutandis to other elements M. More preferably, the sol or the organically modified inorganic hybrid material is obtained from one or more hydrolyzable and condensable silanes, at least one silane optionally having a nonhydrolyzable organic radical. Particular preference is given to using one or more silanes having the following general formulae (I) and/or (II):

SiX₄ (I)

in which the X radicals are the same or different and are each hydrolyzable groups or hydroxyl groups,

RₐSiX₍₄₋ₐ₎ (II)

in which R is the same or different and is a nonhydrolyzable radical which optionally has a functional group, X is as defined above and a has the value of 1, 2 or 3, preferably 1 or 2.

In the above formulae, the hydrolyzable X groups are, for example, hydrogen or halogen (F, Cl, Br or I), alkoxy (preferably C₁₋₆-alkoxy, for example methoxy, ethoxy, n-propoxy, i-propoxy and butoxy), aryloxy (preferably C₆₋₁₀-aryloxy, for example phenoxy), acyloxy (preferably C₁₋₆-acyloxy, for example acetoxy or propionyloxy), alkylcarbonyl (preferably C₂₋₇-alkylcarbonyl, for example acetyl), amino, monoalkylamino or dialkylamino having preferably 1 to 12 and especially 1 to 6 carbon atoms in the alkyl group(s).

The nonhydrolyzable R radical is, for example, alkyl(preferably C₁₋₆-alkyl, for example methyl, ethyl, n-propyl, isopropyl, n-butyl, s-butyl and t-butyl, pentyl, hexyl or cyclohexyl), alkenyl (preferably C₂₋₆-alkenyl, for example vinyl, 1-propenyl, 2-propenyl and butenyl), alkynyl (preferably C₂₋₆-alkynyl, for example acetylenyl and propargyl) and aryl (preferably C₆₋₁₀-aryl, for example phenyl and naphthyl).

The R and X radicals mentioned may optionally have one or more customary substituents, for example halogen, ether, phosphoric acid, sulfo, cyano, amide-, mercapto, thioether or alkoxy groups, as functional groups.

The R radical may contain a functional group through which crosslinking is possible. Specific examples of the functional groups of the R radical are epoxy, hydroxyl, amino, monoalkylamino, dialkylamino, carboxyl, allyl, vinyl, acryloyl, acryloyloxy, methacryloyl, methacryloyloxy, cyano, aldehyde and alkylcarbonyl groups. These groups are preferably bonded to the silicon atom via alkylene, alkenylene or arylene bridging groups which may be interrupted by oxygen or sulfur atoms or —NH— groups. The bridging groups mentioned derive, for example, from the abovementioned alkyl, alkenyl or aryl radicals. The bridging groups of the R radicals contain preferably 1 to 18 and especially 1 to 8 carbon atoms.

Particularly preferred hydrolyzable silanes of the general formula (I) are tetraalkoxysilanes, such as tetramethoxysilane and especially tetraethoxysilane (TEOS). Inorganic sols obtained by acidic catalysis, for example TEOS hydrolyzates, are particularly preferred. Particularly preferred organosilanes of the general formula (II) are epoxysilanes such as 3-glycidyloxypropyltrimethoxysilane (GPTS), methacryloyloxypropyltrimethoxysilane and acryloyloxypropyltrimethoxysilane, and GPTS hydrolyzates are usable advantageously.

If an organically modified inorganic hybrid material is prepared, it is possible to use exclusively silanes of the formula (II) or a mixture of silanes of the formulae (I) and (II). In the inorganic silicon-based sols, exclusively silanes of the formula (I) are used, optionally with addition of proportions of hydrolyzable compounds of the above formula MXₙ.

Particular preference is given to organically modified inorganic hybrid materials which are prepared from titanium-based sols. It is also possible to add silanes of the formulae (I) and/or (II).

If the inorganic sol consists of discrete oxide particles dispersed in the solvent, they can improve the hardness of the layer. These particles are especially nanoscale inorganic particles. The particle size (volume average determined by radiography) is, for example, in the range below 200 nm, especially below 100 nm, preferably below 50 nm, for example 1 nm to 20 nm.

According to the invention, it is possible, for example, to use inorganic sols of SiO₂, ZrO₂, GeO₂, CeO₂, ZnO, Ta₂O₅, SnO₂ and Al₂O₃ (in all polymorphs, especially in the form of boehmite AlO(OH)), preferably sols of SiO₂, Al₂O₃, ZrO₂, GeO₂ and mixtures thereof, as nanoscale particles. Some sols of this kind are also commercially available, for example silica sols, such as the Levasils® from Bayer AG.

The inorganic or organically modified inorganic matrix-forming material used may also be a combination of such nanoscale particles with organically modified hybrid materials or inorganic sols present in the form of hydrolyzates or (poly)condensates, which are referred to here as nanocomposites.

It is optionally also possible for organic monomers, oligomers or polymers of all kinds to be present as organic matrix-forming materials which serve as flexibilizers, and these may be standard organic binders. These can be used to improve coatability. In general, they are degraded photocatalytically on completion of the layer. The oligomers and polymers may have functional groups through which crosslinking is possible. This possibility of crosslinking is also optionally possible in the case of the above-detailed organically modified inorganic matrix-forming materials. Also possible are mixtures of inorganic, organically modified inorganic and/or organic matrix-forming materials.

Examples of usable organic matrix-forming materials are polymers and/or oligomers having polar groups, such as hydroxyl, primary, secondary or tertiary amino, carboxyl or carboxylate groups. Typical examples are polyvinyl alcohol, polyvinylpyrrolidone, polyacrylamide, polyvinylpyridine, polyallylamine, polyacrylic acid, polyvinyl acetate, polymethacrylic acid, starch, gum arabic, other polymeric alcohols, for example polyethylene-polyvinyl alcohol copolymers, polyethylene glycol, polypropylene glycol and poly(4-vinylphenol), or monomers or oligomers derived therefrom.

As already mentioned above, in the case of substrates which consist of a sensitive material or have a surface layer (for example a paint or enamel layer) of such a sensitive material, direct application is possible only with difficulty, if at all. A barrier layer may be arranged between the substrate (optionally with surface coating) and the photocatalytic layer. For this purpose, an inorganic layer of an inorganic matrix-forming material may be used. For this purpose, the above-described inorganic sols may be used.

It is also possible to produce a photocatalytic layer with “incorporated” barrier layer, by forming a concentration gradient of photocatalytically active nanorods in the photocatalytic layer. This can be achieved, for example, with a surface modification of the nanorods with fluorinated organic groups.

The matrix-forming material may also additionally comprise titanium dioxide, for example as amorphous TiO₂, TiO₂ nanoparticles or TiO₂ nanorods. These constituents may be present in a proportion between 10% by weight and 80% by weight, based on the composition of the matrix-forming material, in the preparation of the initiator composition, preferably between 25% by weight and 65% by weight.

The compounds mentioned above as matrix-forming components can also be used for the pretreatment of the substrate in the application and curing of the organic-inorganic coating. It is possible either to use sols or to apply a solution of a hydrolyzable metal compound.

Preference is given to applying a solution of a silane of the formula II. Particular preference is given to silanes of the formula II in which R contains a functional group through which crosslinking is possible. Specific examples of the functional groups of the R radical are epoxy, hydroxyl, amino, monoalkylamino, dialkylamino, carboxyl, allyl, vinyl, acryloyl, acryloyloxy, methacryloyl, methacryloyloxy, cyano, aldehyde and alkylcarbonyl groups. These groups are preferably bonded to the silicon atom via alkylene, alkenylene or arylene bridging groups which may be interrupted by oxygen or sulfur atoms or —NH— groups. The bridging groups mentioned derive, for example, from the abovementioned alkyl, alkenyl or aryl radicals. The bridging groups of the R radicals contain preferably 1 to 18 and especially 1 to 8 carbon atoms.

Particularly preferred organosilanes are epoxysilanes such as 3-glycidyloxypropyltrimethoxysilane (GPTS), methacryloyloxypropyltrimethoxysilane (MPTS) and acryloyloxypropyltrimethoxysilane.

After application, the layer is dried and crosslinked in accordance with the functional group thereof. This may entail the addition of crosslinking initiators.

After the process, further layers may also be applied, for example in order to protect the coated surface of the substrate against UV radiation.

A particular advantage of the process according to the invention is that the compositions used are applied to the substrates in a simple manner. The initiator layer with the nanorods enables the production of particularly fine structures in only a few steps. For this purpose, all known printing processes are used, such as inkjet printing, intaglio printing, screen printing, offset printing or relief printing and flexographic printing. Often, for the printing of the electrical functionalities, combination prints of the aforementioned printing processes are also used. It may be necessary to match the printing plates or rollers or stamps used to the properties of the compositions, for example by matching the surface energy thereof.

There is actually no restriction in the structures applied by structuring. For instance, it is possible to apply connected structures such as conductor tracks. In addition, it is also possible to apply point structures. Owing to the good resolution, it is possible by the process to apply conductive dots invisible to the eye to a film. This is very important in the production of surfaces for touchscreens.

The invention also relates to a coated substrate obtained by the process according to the invention. Such a substrate features an initiator layer comprising photocatalytically active nanorods. This layer has a thickness between 50 nm and 200 μm. Preferred layer thicknesses are between 100 nm and 1 μm, preferably 50 nm to 700 nm. The layer thickness may also be between 20 and 70 μm. The layer may also comprise a matrix material, as already described for the process. Preference is given to an organically modified inorganic matrix material.

On this layer is applied, at least in a region of the surface of the initiator layer, a metal layer. This layer is only up to 200 nm. Preferred layer thicknesses are between 20 and 100 nm, preferably 50 nm to 100 nm. As metals especially copper, silver, gold, nickel, zinc, aluminum, titanium, chromium, manganese, tungsten, platinum or palladium are preferred, preferably silver or gold.

In a development of the invention, the metal layer has, atop the initiator layer, structuring with structural elements having a dimension of less than 50 μm, preferably less than 10 μm. The structural elements may be metallic and/or nonmetallic regions.

In a particularly advantageous development of the invention, the coated substrate has metallic structures which are at least partly transparent. This can be achieved, for example, by the application of structures having a resolution of less than 20 μm to a transparent substrate, preferably less than 10 μm.

The coated substrates which are obtained by the process according to the invention can be used for many applications. Firstly, the process is suitable for application of reflective metal layers to surfaces. These can be used, for example, as reflective layers in holographic applications.

A particular advantage of the invention lies in the production of conductive structures. These are suitable as conductor tracks in electronic applications, especially in touchscreen displays, solar collectors, displays, as RFID antennas or in transistors. They are therefore suitable as a substitute in products which have to date been produced on the basis of ITO (indium tin oxide), for example in TCO coatings (TCO: transparent conductive oxide).

However, the structures can also be used in the transistors sector.

Further details and features are evident from the description of preferred working examples which follows in conjunction with the dependent claims. It is possible here for the particular features to be implemented alone, or several in combination with one another. The means of solving the problem are not restricted to the working examples. For example, stated ranges always include all unspecified intermediate values and all conceivable component intervals.

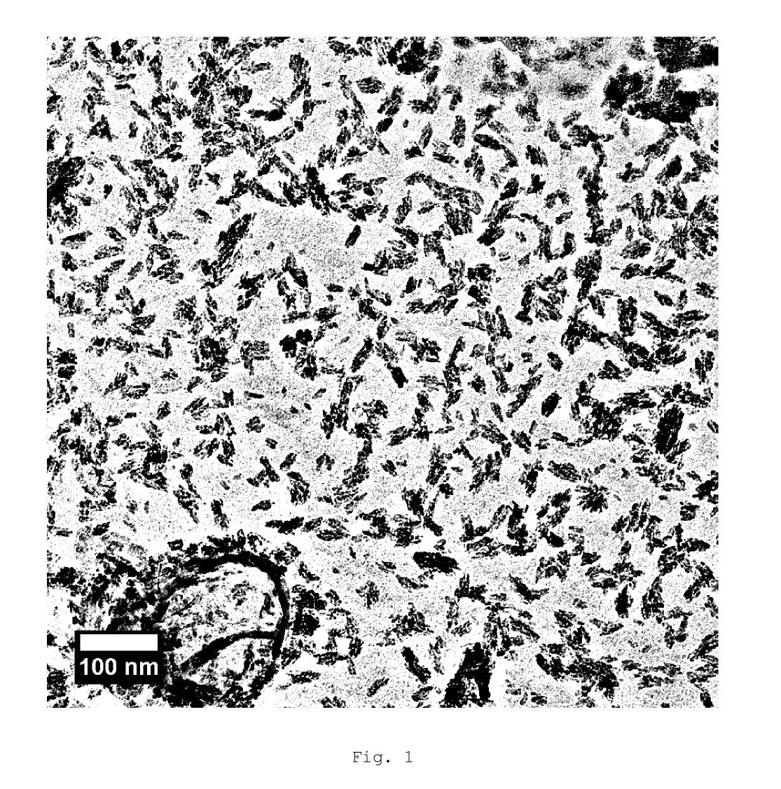

FIG. 1 TEM image of nanorods of TiO₂;

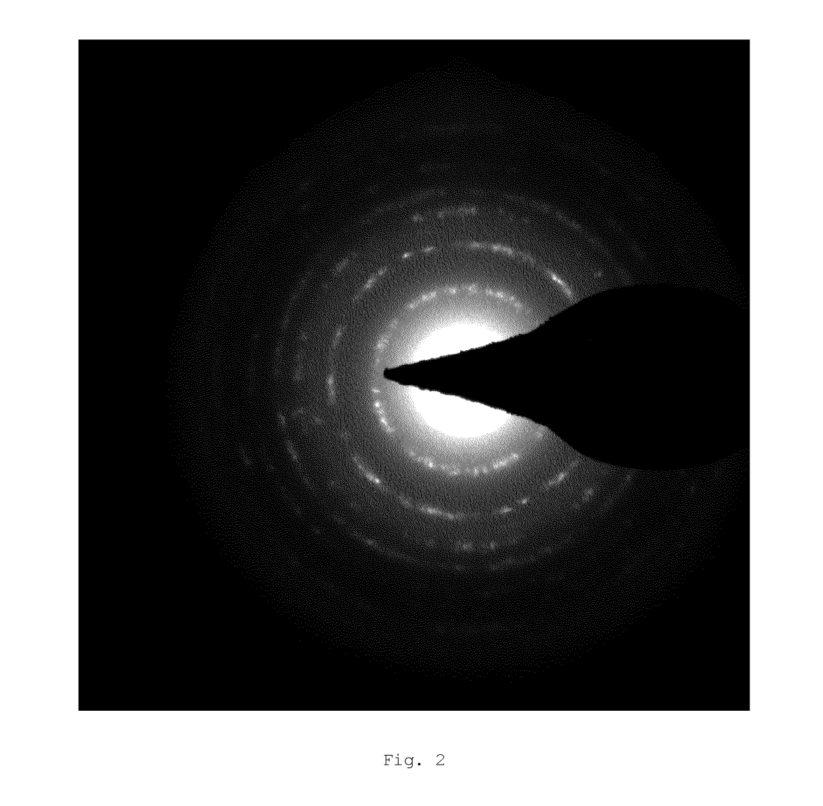

FIG. 2 electron diffractogram of the nanorods;

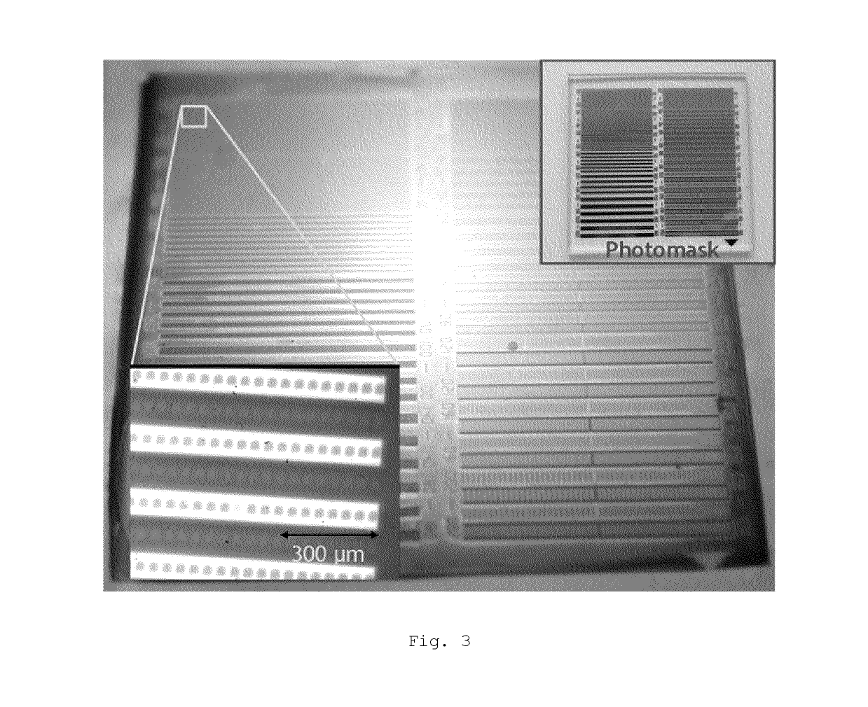

FIG. 3 mask for structuring;

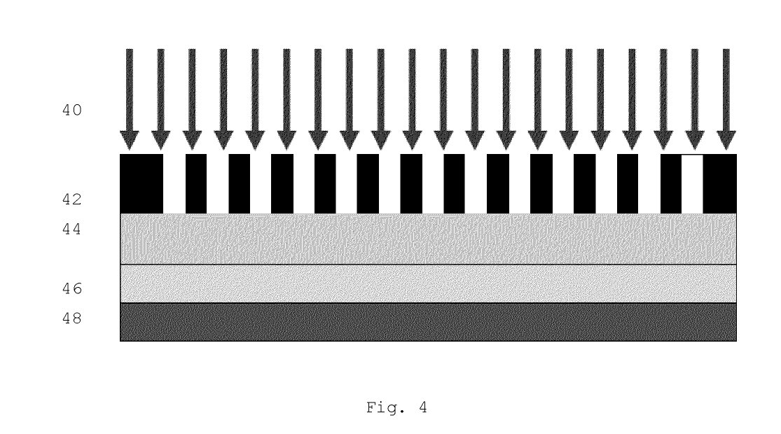

FIG. 4 schematic diagram of exposure through a mask (40: UV light; 42: mask; 44: precursor composition; 46: initiator layer; 48: substrate);

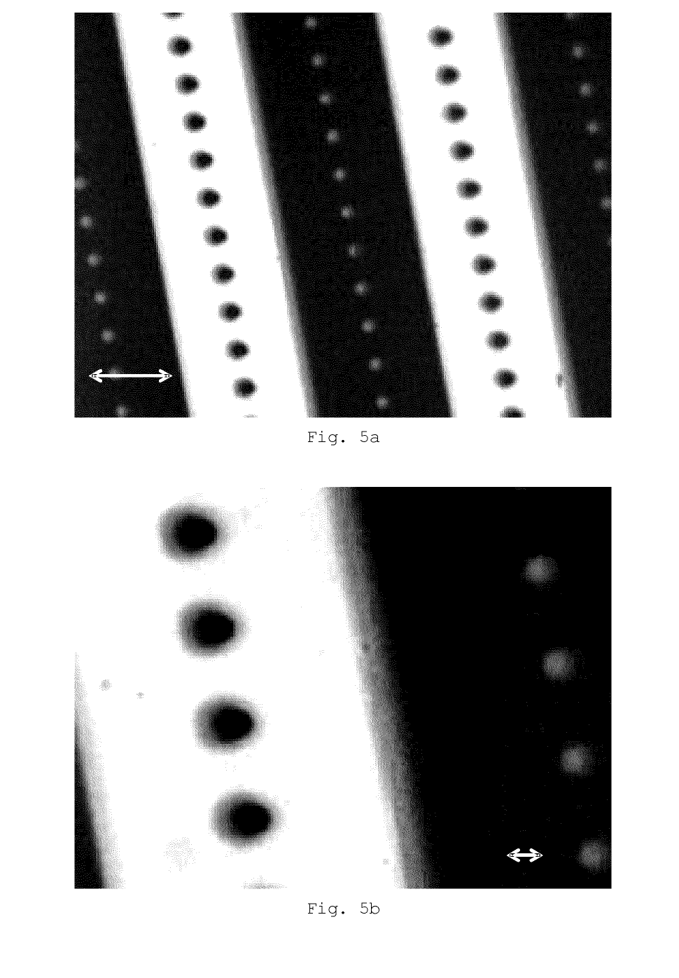

FIG. 5 silver coating using lyothermally produced TiO₂ nanoparticles (a) 10× magnification, scale 100 μm; (b) 50× magnification, scale 10 μm;

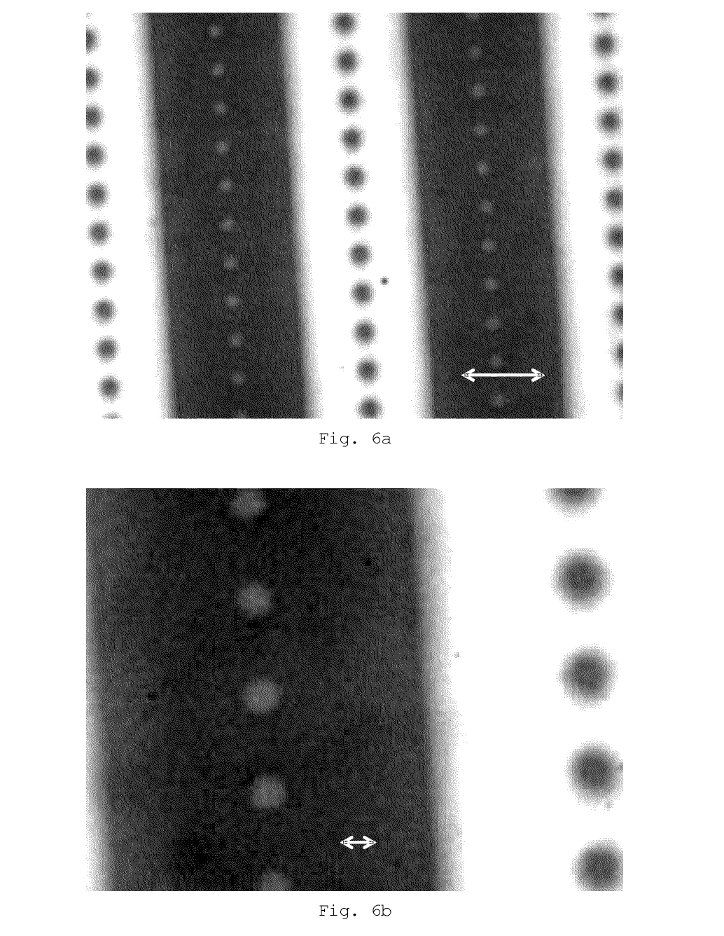

FIG. 6 silver coating using “TiO₂ nanoflakes” (a) 10× magnification, scale 100 μm; (b) 50× magnification, scale 10 μm;

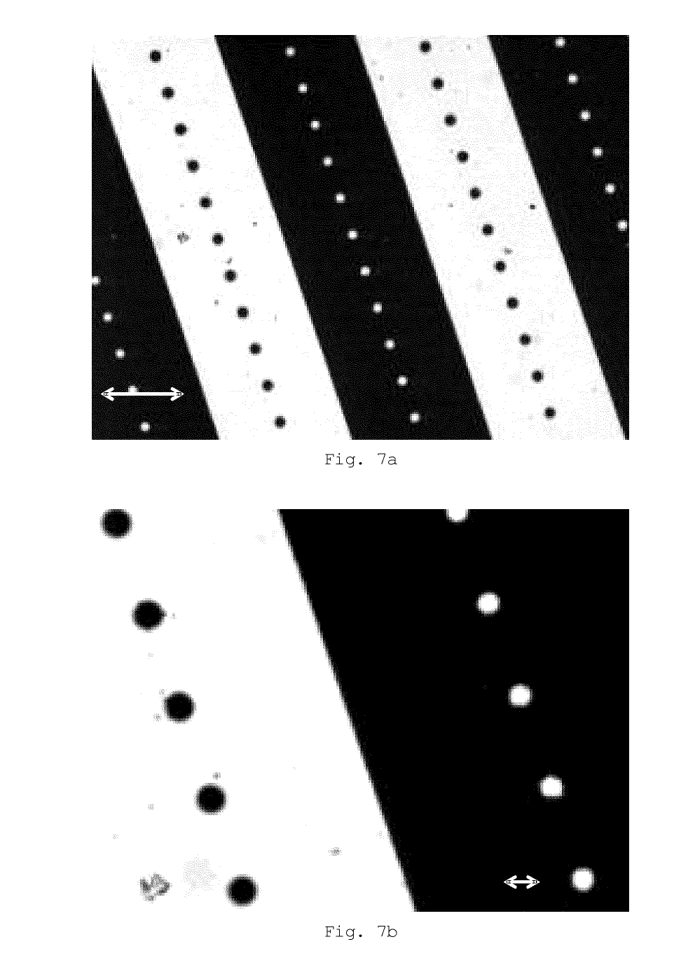

FIG. 7 silver coating using nanorods of Tio₂ (a) 10× magnification, scale 100 μm; (b) 50× magnification, scale 10 μm; and

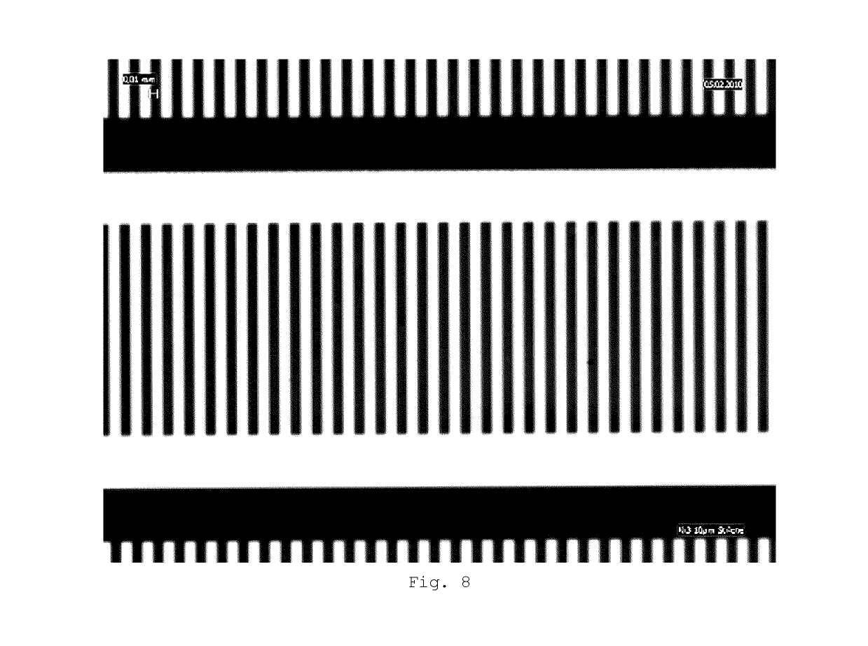

FIG. 8 micrograph of a structure exposed through the mask.

FIG. 1 shows a TEM image (transmission electron microscope) of inventive nanorods of TiO₂. The elongation thereof is clearly evident.

FIG. 2 shows a diffractogram of nanorods of TiO₂. The reflections demonstrate the crystalline structure of the nanorods.

FIG. 3 shows a photomask made of quartz for performance of a structuring operation on exposure. The inset bottom left shows a section enlargement. The mask has structures in an order of magnitude of >100 μm to 10 μm.

FIG. 4 shows a schematic diagram of exposure through a mask. On the substrate (48) is an initiator layer (46) comprising the photocatalytically active nanorods. A layer of precursor composition (44) has been applied thereon. This layer may be a solution present on the surface of the initiator layer. Above this layer is arranged a mask (42) comprising transparent and non-transparent regions shown in black. The effect of the mask is that the incident UV light (40) can pass only through the transparent region of the mask (42) to the precursor composition (44) and reduce the precursor compound in the precursor composition there to the metal. In the unexposed regions, no metal is deposited.

FIGS. 5a, 5b, 6a, 6b, 7a and 7b show the influences of the initiator composition on the quality and sharpness of the structures obtained. The samples were each treated in the same way. However, different kinds of photocatalytic TiO₂ were used for the initiator compositions. Thus, TiO₂ nanoparticles were first produced analogously to the particles used in the document US 2009/0269510 A1 (lyo-TiO₂). FIGS. 6a and 6b show the results for “TiO₂ nanoflakes” composed of anatase TiO₂ having a thickness of 1-5 nm and a lateral dimension of <20 nm. In addition, TiO₂ nanorods were used in one experiment. For all experiments, the same amounts in % by weight were used, and coated and exposed under identical conditions.

The inventive nanorods lead to a distinct improvement in the sharpness of the metal deposition. Even fine structures of less than 10 μm can be clearly resolved. This includes both silver dots and uncoated dots within a silver area. The structures are, more particularly, much sharper than the structures with the particles from US 2009/0269510 A1.

FIG. 8 shows a further section from the structure exposed through the mask. Each of the narrow lines has a width of only 10 μm. This shows the high resolution of the process according to the invention.

Numerous modifications and developments of the working examples described can be implemented.

### EXAMPLES

(1) Substrates Used

The substrates used were various films and glasses. For instance, the films used were polyethylene terephthalate films or polyimide films, and the glasses used were soda-lime glass or borosilicate glass. The size of the substrates varied between 5 cm×5 cm and cm×10 cm. The thickness of the substrates varied between 0.075 mm and 5 mm.

(2) Production of the Nanorods

Method taken from: Jia, Huimin et al., Materials Research Bulletin, 2009, 44, 1312-1316, “Nonaqueous sol-gel synthesis and growth mechanism of single crystalline TiO₂ nanorods with high photocatalytic activity”.

240 ml of benzyl alcohol were initially charged in a 500 ml Schott bottle with a stirrer flea. Subsequently, everything (benzyl alcohol, syringe, titanium tetrachloride) was introduced into a glovebag under argon, the benzyl alcohol bottle was opened and the bag was flushed twice with argon (=filled with Ar and partly emptied and filled again) while stirring vigorously. By means of a 20 ml syringe and a long cannula, 12 ml of TiCl₄ were withdrawn, the cannula was removed from the syringe and the TiCl₄ was added dropwise to the benzyl alcohol while stirring vigorously.

Every drop of TiCl₄ added caused a noise like a crack or bang, and significant evolution of smoke was observed. At the same time, the solution turned an intense red and heated up. On completion of addition, the solution was an intense orange-yellow color and red agglomerates had formed. The mixture was left to stir with the lid open under an Ar atmosphere for another ˜1 h and then taken out of the glovebag. The solution was then intense yellow in color with several small and somewhat thicker white/yellow agglomerates.

Under a fume hood, the mixture was then left open to stir for another ˜1 h, before being divided into two Teflon vessels without the thicker lumps (˜130 g each) and autoclaved (pressure digestion: in block A; time: 2×23 h 59 min; temp.: 80° C.)

The supernatant in both Teflon vessels was removed by means of a pipette, and the gel-like white precipitate was slurried, introduced into centrifuge tubes and centrifuged (15 min; at 2000 RCF; at RT; braking power: 0). The centrifugate was decanted and chloroform was added to the residue. The mixtures were left to stand overnight.

The centrifuge tubes were balanced out in pairs with chloroform, shaken properly until no larger agglomerates were observable any longer, and centrifuged (15 min; 3000 RCF; RT; braking power: 0). The centrifugate was decanted again and chloroform was again added to the residue. Subsequently, the further procedure was as described above (without leaving to stand overnight). Overall, the particles were washed three times with chloroform.

After the last decanting operation, the centrifuge tubes were left open to stand under a fume hood overnight and, the next morning, the dried nanorods were transferred into a snap-lid bottle.

### (3) Preparation of the Silver Complex Solution

0.1284 g (1.06 mmol) of TRIS (tris(hydroxymethyl)aminomethane) was dissolved in 0.5 g (27.75 mmol) of deionized H₂O and 0.5 g (10.85 mmol) of EtOH. In addition, 0.0845 g (0.5 mmol) of AgNO₃ was dissolved in 0.5 g (27.75 mmol) of deionized H₂O and 0.5 g (10.85 mmol) of EtOH. The AgNO₃ solution was added to the first solution while stirring. The solution of the metal complex formed was colorless and clear. The solution can also be prepared in pure deionized water.

### (4) Preparation of a Gold Complex Solution

0.1926 g (1.59 mmol) of TRIS (tris(hydroxymethyl)aminomethane) was dissolved in 0.5 g (27.75 mmol) of deionized H₂O and 0.5 g (10.85 mmol) of EtOH. In addition, 0.1517 g (0.5 mmol) of AuCl₃ or 0.1699 g (0.5 mmol) of HAuCl₄ were dissolved in 0.5 g (27.75 mmol) of deionized H₂O and 0.5 g (10.85 mmol) of EtOH. The AuCl₃ or HAuCl₄ solution was added to the solution of the ligand while stirring. The complex solution formed was colorless to yellowish and clear. The solution can also be prepared in pure deionized water.

(5) Lyothermal Synthesis of TiO₂ Particles (lyo-TiO₂)

48.53 g of Ti (O-i-Pr)₄ were added to 52.73 g of 1-PrOH (n-propanol). To this solution was slowly added dropwise a solution of hydrochloric acid (37%, 3.34 g) and 10.00 g of 1-PrOH. To this solution was then added dropwise a mixture of 4.02 g of H₂O and 20.00 g of 1-PrOH. The solution obtained may be pale yellow in color and was transferred to a pressure digestion vessel (approx. 130 g). In this vessel, the solution was treated at 210° C. for 2.5 h.

The mixture was decanted and the particles obtained were transferred to a flask and the solvent was removed at 40° C. in a rotary evaporator under reduced pressure.

For further use, the particles obtained were suspended in water.

### (6) General Use

The steps which follow were conducted for each sample. The substrates were pre-cleaned with ethanol, propanol and lint-free tissues. The various suspensions were applied either by flow coating or by knife coating. The TiO₂ layers obtained were dried in an oven at temperatures between 100° C. and 150° C., especially at 120° C. or 140° C., for 5 to 30 minutes. Thereafter, the substrates were rinsed with deionized water to remove residues, and dried with compressed air.

Thereafter, the solution of the silver complex was applied and irradiated with UV radiation. Thereafter, the excess silver complex was removed by rinsing with deionized water and the coated substrates were dried with compressed air. The light source used was a mercury-xenon lamp (LOT-Oriel solar simulator, 1000 W, focused onto an area of 10 cm×10 cm). The intensity of the lamp was measured with the “UV-Integrator” digital measuring instrument (BELTRON) and was 55 mW/cm² within the spectral range from 250 to 410 nm.

### (7) Suspensions of TiO₂ Nanorods in H₂O/EtOH

First of all, the TiO₂ nanorods were suspended in deionized water. Thereafter, an appropriate amount of ethanol was added. In all suspensions, the ratio of H₂O and EtOH in the suspensions was H₂O:EtOH→20:80 in % by weight or 10:90 in % by weight. For the production of TiO₂ layers, the following suspensions were prepared:
2.5% by weight of TiO₂ nanorods in H₂O/EtOH
2.0% by weight TiO₂ nanorods in H₂O/EtOH
1.5% by weight TiO₂ nanorods in H₂O/EtOH
1.0% by weight TiO₂ nanorods in H₂O/EtOH

### (8) MPTS as Primer

It was possible to distinctly improve the quality of the TiO₂ layers, especially on the films, by prior application of a coating of MPTS (methacryloyloxypropyltrimethoxysilane). For this purpose, such a layer was applied prior to the TiO₂ layers. The substrates were coated by flow-coating with a 1.0% by weight MPTS solution in butyl acetate. The MPTS layer was cured photochemically. Thereafter, the TiO₂ layer was applied as described under (6).

(9) Plasma treatment

It was also found that the quality of the TiO₂ layers, especially on films, can be improved by a pretreatment with plasma. The clean substrates were treated with a 600 watt oxygen plasma for 1.5 minutes. Thereafter, the TiO₂ layer was applied as described under (6).

### (10) Flame Treatment of the Film Substrate

It was possible to achieve an improvement in the wetting of film substrates with the suspension of the TiO₂ nanorods by prior flame treatment with silane. For this purpose, the cleaned film substrates were treated with a flame at a distance of about 15 cm for a few seconds. Thereafter, the TiO₂ layer was applied as described under (6).

### (11) Application of the TiO₂ Layer to a Porous SiO₂ Layer

The suspension of TiO₂ nanorods was applied by flow coating to a porous SiO₂ layer on glass. For this purpose, a standard SiO₂ sol was used.

(12) Suspensions of TiO₂ Nanorods with H Sol

First, an H sol was prepared. This is a yellow solution containing amorphous titanium dioxide. For this purpose, 396.2 g (1.39 mol) of Ti(O-i-Pr)₄ [CAS: 546-68-9] were added to 2869.2 g of 2-propanol. 139.3 g (1.39 mol) of acetylacetone [CAS: 123-54-6] were added while stirring. The mixture was stirred at room temperature for 15 minutes. A solution of 38.7 g of water and 92.64 g of 37% HCl [CAS: 7647-01-0] was added gradually to the mixture. The mixture was stirred at room temperature for 24 hours and stored at 4° C. The total volume of the mixture is about 4.5 l. In order to improve the wettability of the suspension, H sol was added to a suspension of TiO₂ nanorods. The amount of H sol is based on the mass of suspension used. The following mixtures were prepared:
(1.5% by weight of TiO₂ suspension)+13% by weight of H sol
(1.5% by weight of TiO₂ suspension)+15% by weight of H sol
(1.0% by weight of TiO₂ suspension)+6.5% by weight of H sol
(1.0% by weight of TiO₂ suspension)+10% by weight of H sol
(0.5% by weight of TiO₂ suspension)+2.5% by weight of H sol
(0.5% by weight of TiO₂ suspension)+5.0% by weight of H sol

The suspensions were applied by flow-coating to cleaned PET film. After drying at 120° C. for about 10 minutes, slightly cloudy layers were obtained.

The mixtures obtained were applied as described under (6).

### (13) TiO₂ Nanorods in the GTI Sol System

GTI is a water-based sol system based essentially on (3-glycidyloxypropyl)triethoxysilane (GPTES) and titanium (IV) isopropoxide. For preparation, the GPTES is initially charged (4 mol, e.g. 58.922 g) in a 250 ml one-neck flask. Subsequently, titanium isopropoxide (1 mol, e.g. 15.037 g and glacial acetic acid (4 mol, e.g. 12.708 g) are added while stirring. After homogenization, water is added (14 mol, H₂O or particle suspension, e.g. 13.333 g of H₂O). In the course of this, the mixture starts to gelate; nevertheless, the total amount of water is added. The mixture is left to stand on the stirrer and becomes liquid again after a certain time. The mole figures serve to illustrate the ratios. Any particle or nanowire suspensions are added in an appropriate amount in place of the water.

During the preparation, the TiO₂ nanorods were added to the sol such that the TiO₂ nanorods make up about 60% by weight of the solids content of the coating composition. Since the sol obtained was somewhat viscous, it was applied with a coating bar. In addition, in some compositions, the GTI sol was diluted ⅓ to ⅕ with ethanol.

The titanium (IV) isopropoxide can also be replaced by TEOS or MTEOS or a mixture of the two. It is thus possible to obtain a whole series of different compositions.

Suspensions of TiO₂ Nanorods with GTI Sol Comprising TiO₂ Nanorods

The GTI sol comprising the TiO₂ nanorods was added to the suspension of TiO₂ nanorods according to the mass of the suspension. The following mixtures were prepared:
(1.5% by weight of TiO₂ nanorod suspension)+5% by weight of GTI (60% by weight of TiO₂ nanorods)
(1.5% by weight of TiO₂ nanorod suspension)+10% by weight of GTI (60% by weight of TiO₂ nanorods)
(1.5% by weight of TiO₂ nanorod suspension)+20% by weight of GTI (60% by weight of TiO₂ nanorods)

The mixtures obtained were applied as described under (6).

### (14) Suspensions of TiO₂ Nanorods Comprising GTI Sol and TiO₂ Nanoparticles

For the production of these coating compositions, titanium dioxide nanoparticles (lyo-TiO₂ having a size between 7 and 10 nm) were added to the GTI sol during the preparation. The content of TiO₂ nanoparticles in the GTI sol was between 20% by weight and 95% by weight, preferably 30% by weight or 60% by weight. The sol produced was added to the suspensions of TiO₂ nanorods based on the mass of the suspension. The following mixtures were prepared:
(1.5% by weight of TiO₂ nanorod suspension)+10% by weight of GTI (30% by weight of TiO₂ nanoparticles)
(1.5% by weight of TiO₂ nanorod suspension)+5% by weight of GTI (30% by weight of TiO₂ nanoparticles)
(1.5% by weight of TiO₂ nanorod suspension)+10% by weight of GTI (60% by weight of TiO₂ nanoparticles)

The mixtures obtained were applied as described under (6).

(15) Suspensions of TiO₂ Nanorods with DEG/MEG

DEG (diethylene glycol) or MEG (monoethylene glycol) were also added to the suspensions of TiO₂ nanorods, based on the mass of suspension used. The following mixtures were prepared:
(1.5% by weight of TiO₂ nanorod suspension)+4.0% by weight of DEG
(1.5% by weight of TiO₂ nanorod suspension)+3.5% by weight of DEG
(1.5% by weight of TiO₂ nanorod suspension)+3.0% by weight of DEG
(1.5% by weight of TiO₂ nanorod suspension)+4.0% by weight of MEG
(1.5% by weight of TiO₂ nanorod suspension)+3.0% by weight of MEG

The mixtures obtained were applied as described under (6).

### (16) Laminar Deposition of Silver

The TiO₂ coatings produced were washed with deionized water and dried with compressed air. Thereafter, the solution comprising the silver complex was applied as follows: an elastic frame was placed onto the coated substrate and the solution comprising the silver complex was introduced into the frame. It was possible to vary the thickness of the liquid layer in the frame between 30 μm and 2 mm depending on the frame used. Thereafter, the substrates were irradiated with UV light for a period between 1 and 5 minutes. The excess silver complex was washed away with deionized water and the substrates were dried.

### (17) Production of the Silver Microstructures

The substrates (e.g. glass, PMMA, PET, PVC, PS, . . . ) were coated with TiO₂ nanorods. The TiO₂ coatings produced were washed with deionized water and dried with compressed air. Transparent coatings were obtained. Thereafter, the coated surface was wetted with the solution with the silver complex. A quartz mask having a fine structure was applied to the substrate. The substrate was then irradiated through the mask with UV light (e.g. LOT-Oriel solar simulator, 1000 W Hg(Xe) light source, focused onto an area of 10×10 cm²) for 20 s to 5 minutes. The mask was removed and the excess silver complex was removed by washing. Thereafter, the substrates were dried. Optionally, a further protective layer was applied or laminated on. This operation gives structures having a resolution of 10 μm.

### (18) Production of a Silver Microstructure

A 0.075 mm-thick, precleaned PET film was coated by flow-coating with a suspension comprising 2.5% by weight of TiO₂ nanorods in H₂O/EtOH. The ratio of H₂O and EtOH in the suspension was 10% by weight of H₂O and 90% by weight of EtOH. The layer of TiO₂ obtained was dried in an oven at 120° C. for 30 minutes. Thereafter, the substrate was rinsed with deionized water and dried with compressed air. The solution of the silver complex was dripped onto the surface and a mask made of quartz glass was applied to the substrate. The distance of the mask from the surface of the initiator layer, and hence the layer thickness of the precursor composition, was 200 μm. This was followed by exposure with UV light through the mask for 5 minutes. The mask was removed and the excess silver complex was washed off. Thereafter, the substrate was dried.

### (19) Measurement of the Conductivity of Coatings

### Sample a)

A 2.0 mm-thick, cleaned sheet of borosilicate glass (5×5 cm²) was coated by flow-coating with a suspension of 1.5% by weight of TiO₂ nanorods in H₂O/EtOH. The ratio of H₂O and EtOH in the suspension was 10% by weight of H₂O and 90% by weight of EtOH. The layer of TiO₂ obtained was dried in an oven at 120° C. for 20 minutes. Thereafter, the substrate was rinsed off with deionized water and dried with compressed air. Thereafter, silver was deposited over the whole surface area. An elastic frame was placed onto the coating and the solution of the silver complex was introduced into the frame. The height of the solution in the frame was 2 mm. Thereafter, the substrate was exposed with UV light for 1 minute. The excess silver complex solution was washed off with deionized water and the coated substrate was dried.

### Sample b)

A 2.0 mm-thick, cleaned sheet of borosilicate glass (5×5 cm²) was coated by flow-coating with a suspension of 1.5% by weight of TiO₂ nanorods in H₂O/EtOH. The ratio of H₂O and EtOH in the suspension was 10% by weight of H₂O and 90% by weight of EtOH. The layer of TiO₂ obtained was dried in an oven at 120° C. for 20 minutes. Thereafter, the substrate was rinsed off with deionized water and dried with compressed air. Thereafter, silver was deposited over the whole surface area. An elastic frame was placed onto the coating and the solution of the silver complex was introduced into the frame. The height of the solution in the frame was 2 mm. Thereafter, the substrate was exposed with UV light for 3 minutes. The excess silver complex solution was washed off with deionized water and the coated substrate was dried.

### Sample c)

A 2.0 mm-thick, cleaned sheet of borosilicate glass (5×5 cm²) was coated by flow-coating with a suspension of 1.5% by weight of TiO₂ nanorods comprising 5% by weight of GTI sol (60% by weight of TiO₂ nanorods) based on the mass of the TiO₂ suspension. The layer of TiO₂ obtained was dried in an oven at 120° C. for 20 minutes. Thereafter, the substrate was rinsed off with deionized water and dried with compressed air. Thereafter, silver was deposited over the whole surface area. An elastic frame was placed onto the coating and the solution of the silver complex was introduced into the frame. The height of the solution in the frame was 2 mm. Thereafter, the substrate was exposed with UV light for 1 minute. The excess silver complex solution was washed off with deionized water and the coated substrate was dried.

### Sample d)

A 2.0 mm-thick, cleaned sheet of borosilicate glass (5×5 cm²) was coated by flow-coating with a suspension of 1.5% by weight of TiO₂ nanorods comprising 5% by weight of GTI sol (60% by weight of TiO₂ nanorods) based on the mass of the TiO₂ suspension. The layer of TiO₂ obtained was dried in an oven at 120° C. for 20 minutes. Thereafter, the substrate was rinsed off with deionized water and dried with compressed air. Thereafter, silver was deposited over the whole surface area. An elastic frame was placed onto the coating and the solution of the silver complex was introduced into the frame. The height of the solution in the frame was 2 mm. Thereafter, the substrate was exposed with UV light for 3 minutes. The excess silver complex solution was washed off with deionized water and the coated substrate was dried.

### Measurement of Conductivity

The conductivity was measured by means of a four-point measuring instrument at 5 different points on each of the Ag layers. The measurements were subsequently used to form the mean. Table 1 shows the values measured for some substrates. The time figure for the silver layer indicates the duration of irradiation. In the different columns the influence of the duration of the thermal treatment of the initiator layer after the application and before the application of the precursor composition was examined. The duration of thermal treatment leads to a slight improvement in conductivity. Longer irradiation, and hence probably an improvement in reduction of the silver complex, leads to a distinct improvement in conductivity. The second line in each case indicates the areal resistance (pSHEET).

Through the use of only two coating solutions, it was possible in this way to coat a substrate with an amount of silver sufficient for good conductivity. This also allows the employment of the process in a continuous coating system for films.

TABLE 1

| | Measurement | 0 min | 5 min | 10 min | 15 min | 25 min | 35 min | 50 min |
|---|---|---|---|---|---|---|---|---|
| Sample | mode | 120° C. | 120° C. | 120° C. | 120° C. | 120° C. | 120° C. | 120° C. |
| a) | Psheet | 3.1096 Ω | 1.2606 Ω | 1.2154 Ω | 1.1888 Ω | 1.1178 Ω | 1.1998 Ω | 1.0646 Ω |
| boros. | pV/I | 690.44 mΩ | 283.1 mΩ | 271.08 mΩ | 259.62 mΩ | 251.48 mΩ | 260.9 mΩ | 238.16 mΩ |
| glass; | | | | | | | | |
| 1.5% | | | | | | | | |
| nanorods; | | | | | | | | |
| 1 min | | | | | | | | |
| b) | pSHEET | 2.3664 Ω | 850.98 mΩ | 782.72 mΩ | 753.16 mΩ | 723.42 mΩ | 728.9 mΩ | 681.38 mΩ |
| boros. | pV/I | 513.16 mΩ | 184.64 mΩ | 175.02 mΩ | 167.38 mΩ | 161.08 mΩ | 160.5 mΩ | 147.2 mΩ |
| glass; | | | | | | | | |
| 1.5% | | | | | | | | |
| nanorods; | | | | | | | | |
| 3 min | | | | | | | | |
| c) | pSHEET | 9.4432 Ω | 3.012 Ω | 3.013 Ω | 2.9076 Ω | 2.9938 Ω | 3.205 Ω | 3.0704 Ω |
| boros. | pV/I | 2.0688 Ω | 697.6 mΩ | 658.7 mΩ | 699.32 mΩ | 654.3 mΩ | 706.5 mΩ | 705.66 mΩ |
| glass; | | | | | | | | |
| 1.5% | | | | | | | | |
| nanorods + | | | | | | | | |
| GTI; | | | | | | | | |
| 1 min | | | | | | | | |
| d) | pSHEET | 2.9536 Ω | 825.28 mΩ | 794.54 mΩ | 768.9 mΩ | 736.22 mΩ | 743.12 mΩ | 691.76 mΩ |
| boros. | pV/I | 651.7 mΩ | 183.82 mΩ | 174.02 mΩ | 168.2 mΩ | 160.88 mΩ | 165.04 mΩ | 152.86 mΩ |
| glass; | | | | | | | | |
| 1.5% | | | | | | | | |
| nanorods + | | | | | | | | |
| GTI; | | | | | | | | |
| 3 min | | | | | | | | |

### REFERENCE NUMERALS

40 UV light
42 Mask
44 Precursor composition
46 Initiator layer
48 Substrate

### LITERATURE CITED

U.S. Pat. No. 5,534,312
US 2004/0026258 A1
US 2005/0023957 A1
US 2006/0144713 A1
Noh, C.-, et al., Advances in Resist Technology and Processing XXII, Proceedings of SPIE, 2005, 5753, 879-886, “A novel patterning method of low-resistivity metals”.
Noh, C.-, et al., Chemistry Letters, 2005, 34(1), 82-83, “A novel patterning method of low-resistivity metals”.
US 2009/0269510 A1
Jia, Huimin et al., Materials Research Bulletin, 2009, 44, 1312-1316, “Nonaqueous sol-gel synthesis and growth mechanism of single crystalline TiO₂ nanorods with high photocatalytic activity”.

1. A process for producing metallic structures, comprising the following steps:
(a) applying an initiator composition to a substrate, the composition comprising photocatalytically active nanorods as an initiator;
(b) applying a precursor composition comprising at least one precursor compound for a metal layer to the substrate; and
(c) reducing the precursor compound to the metal by electromagnetic radiation on the initiator.

2. The process as claimed in claim 1, wherein a structuring operation is effected in step (a) and/or in step (b) and/or in step (c).

3. The process as claimed in claim 2, wherein the structuring comprises structures having a minimum lateral dimension of less than 500 μm.

4. The process as claimed in claim 1, wherein the precursor compound comprises a silver, gold or copper complex.

5. The process as claimed in claim 1, wherein the application of the initiator composition is preceded by pretreatment of the surface of the substrate, said pretreatment comprising a plasma treatment, corona treatment, flame treatment and/or the application and curing of an organic-inorganic coating.

6. The process as claimed in claim 1, wherein the nanorods have a ratio of diameter to length between 1000:1 and 2:1.

7. The process as claimed in claim 1, wherein the initiator composition comprises a matrix-forming component.

8. The process as claimed in claim 1, wherein the initiator composition comprises at least one compound having at least 2 polar groups.

9. A coated substrate obtained by the process as claimed in claim 1.

10. The coated substrate as claimed in claim 9, wherein the coated substrate and the metallic structures have an at least partly transparent appearance.

11. (canceled)

12. A conductor track in an electronic application comprising the coated substrate as claimed in claim 9.

13. A touchscreen display comprising the coated substrate as claimed in claim 9.

14. A solar collector comprising the coated substrate as claimed in claim 9.

15. An RFID antenna comprising the coated substrate as claimed in claim 9.

16. A transistor comprising the coated substrate as claimed in claim 9.
